(19) United States
(12) Patent Application Publication
(10) Pub. No.: US 2005/0090111 A1
(43) Pub. Date: Apr. 28, 2005

(54) Magnetic tunnel junction device with etch stop layer and dielectric spacer

(76) Inventor: Heon Lee, Pohang-Si (KR)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/692,773

(22) Filed: Oct. 24, 2003

(51) Int. Cl. H01L 21/311; H01L 21/302; H01L 21/461

(52) U.S. Cl. 438/700

(57) ABSTRACT

A method of making a magnetic tunnel junction device is disclosed. The magnetic tunnel junction device includes a discrete magnetic tunnel junction stack and an electrically non-conductive spacer in contact with a portion of the discrete magnetic tunnel junction stack. The spacer electrically insulates a portion of the magnetic tunnel junction stack from an electrically conductive material used for a dual-damascene conductor that is formed in a self-aligned via this is positioned over the discrete magnetic tunnel junction stack. The method includes forming an electrically conductive etch stop layer on a magnetic tunnel junction stack. In subsequent etching steps, the etch stop layer protects one or more layers of magnetic material in the discrete magnetic tunnel junction stack from chemical erosion caused by an etch material, such as an etch material that includes the chemical fluorine (F), for example.

### FIELD OF THE INVENTION

The present invention relates generally to a method of making a magnetic tunnel junction device. More specifically, the present invention relates to a method of making a magnetic tunnel junction device that includes an electrically non-conductive spacer and a dual damascene conductor that is in contact with an etch stop layer that prevents chemical erosion of one or more layers of a magnetic material of the magnetic tunnel junction device during an etching process.

### BACKGROUND OF THE INVENTION

An magnetoresistance random access memory (MRAM) includes an array of memory cells. Each memory cell is a magnetic tunnel junction device. The magnetic tunnel junction device operates on the principles of spin tunneling. There are several types of magnetic tunnel junction devices including two prominent types, tunneling magnetoresistance (TMR) and giant magnetoresistance (GMR). Both types of devices comprise several layers of thin film materials and include a first layer of magnetic material in which a magnetization is alterable and a second layer of magnetic material in which a magnetization is fixed or “pinned” in a predetermined direction. The first layer is commonly referred to as a data layer or a sense layer; whereas, the second layer is commonly referred to as a reference layer or a pinned layer. The data layer and the reference layer are separated by a very thin tunnel barrier layer. In a TMR device, the tunnel barrier layer is a thin film of a dielectric material (e.g. silicon oxide SiO₂). In contrast, in a GMR device, the tunnel barrier layer is a thin film of an electrically conductive material (e.g. copper Cu).

Electrically conductive traces, commonly referred to as word lines and bit lines, or collectively as write lines, are routed across the array of memory cells with a memory cell positioned at an intersection of a word line and a bit line. The word lines can extend along rows of the array and the bit lines can extend along columns of the array, or vice-versa. A single word line and a single bit line are selected and operate in combination to switch the alterable orientation of magnetization in the memory cell located at the intersection of the selected word and bit lines. A current flows through the selected word and bit lines and generates magnetic fields that collectively act on the alterable orientation of magnetization to cause it to switch (i.e. flip) from a current state (i.e. a logic zero “0”) to a new state (i.e. a logic “1”). Typically, the alterable orientation of magnetization is aligned with an easy axis of the data layer and the magnetic field causes the alterable orientation of magnetization to flip from an orientation that is parallel with the pinned orientation of the reference layer or to an orientation that is anti-parallel to the pinned orientation of the reference layer. The parallel and anti-parallel orientations can represent the logic states of “0” and “1” respectively, or vice-versa.

Because the layers of material that comprise the magnetic tunnel junction device are very thin layers of material (e.g. on the order of about 15.0 nm or less), the manufacturing of defect free magnetic tunnel junction devices can be quite difficult. Those defects can include variations in magnetic switching characteristics among memory cells in the same array, defects in the tunnel barrier layer, and defects in the layer(s) of magnetic materials that comprise the data layer and/or the reference layer. Additionally, magnetic materials are also used for anti-ferromagnetic layers, cap layers, seed layers, and pinning layers, etc.

In FIG. 1a, a prior magnetic tunnel junction device 200 can include a bottom conductor 213 that can be a bit line, a seed layer 211 (e.g. made from tantalum Ta), a pinned layer 209 of a magnetic material (e.g. made from nickel iron NiFe) and including a pinned orientation of magnetization m₁, a tunnel barrier layer 207 (e.g made from aluminum oxide Al₂O₃ for a TMR device), a data layer 205 of a magnetic material (e.g. made from nickel iron cobalt NiFeCo) and including an alterable orientation of magnetization m₂, a cap layer 203 (e.g. made from tantalum Ta), and a top conductor 201 that can be a word line.

In FIG. 1b, one disadvantage to prior methods of manufacturing the magnetic tunnel junction device 200 is that the chemicals used during some of the processing steps can chemically attack or erode the magnetic materials that are used to form some of the thin film layers of the magnetic tunnel junction device 200. For example, a via 224 can be formed by using a plasma or wet etch process P to remove a layer of dielectric material 221 that covers the cap layer 203. Because the layers of material are very thin, during an over etch step, etch materials that are fluoride (F) based can permeate the cap layer 203 and the layers below it, and chemically erode E the magnetic materials in the data layer 205, the reference layer 209, and any other layers that include magnetic materials such as nickel (Ni), iron (Fe), and cobalt (Co), for example.

In FIG. 2, the prior magnetic tunnel junction device 200 includes a magnetic tunnel junction stack 230 that is crossed by and positioned between a column conductor 201 and a row conductor 213. The row and column conductors can be the top and bottom conductors (201, 213) of FIG. 1a. A current Ix flowing in the column conductor 201 generates a magnetic field Hy and a current ly flowing in the row conductor 213 generates a magnetic field Hx. The combined effect of the magnetic fields (Hy, Hx) acting on the alterable orientation of magnetization causes the alterable orientation to flip if a combined magnitude of the magnetic fields (Hy, Hx) is of a sufficient magnitude.

One disadvantage of the prior magnetic tunnel junction device 200 is that shorts created during a manufacturing of the device can significantly reduce manufacturing yields. For example, if during the manufacturing of the prior magnetic tunnel junction device 200, some of the material for the column conductor 201 comes into contact with the row conductor 213 or comes into contact with a side 230c of the magnetic tunnel junction stack 230, then the magnetic tunnel junction device 200 is defective due to a short circuit.

In FIG. 3a, the prior magnetic tunnel junction stack 230 can include a pinned layer 209 of a magnetic material (e.g. made from nickel iron NiF) and including a pinned orientation of magnetization (not shown), a tunnel barrier layer 207 (e.g made from aluminum oxide Al₂O₃ for a TMR device), and a data layer 205 of a magnetic material (e.g. made from nickel iron cobalt NiFeCo) and including an alterable orientation of magnetization (not shown). During manufacturing, a pattern formed by a mask layer 220 is formed on a dielectric layer 221. Ideally, as depicted by dashed lines I, the pattern formed by the mask 220 would be perfectly aligned with the magnetic tunnel junction stack 230. However, in reality, there are errors introduced by the machines and the fabrication processes used to manufacture the prior magnetic tunnel junction device 200. As a result, an actual misalignment depicted by dashed lines A can occur.

In FIG. 3b, the dielectric layer 221 is etched through the mask layer 220 to form a via 233 in the dielectric layer 221. Due to the misalignment, the via 233 extends beyond a top portion of the magnetic tunnel junction stack 230 and exposes a side portion 233m of the magnetic tunnel junction stack 230.

In FIG. 4a, during a metal deposition step, an electrically conductive material 235 fills in the misaligned via 233 including those portions in the side portion 233m which creates a short 235s between the magnetic tunnel junction stack 230 and the row conductor 213. In FIG. 4b, the column conductor 201 is formed on the electrically conductive material 235 resulting in a short 235t between the row and column conductors (213, 201) and the magnetic tunnel junction stack 230.

Another disadvantage to prior methods for manufacturing the magnetic tunnel junction device 200 is that many processing steps are required. As a result, yield can be compromised by any of those steps. For example, the process for forming the top conductor 201 can require several processing steps that can include: in a first step, forming a via in a dielectric layer (not shown) that extends to the data layer 205; filling the via with an electrically conductive material; and then in a second step, depositing another electrically conductive material to form the top conductor 201. Generally, more processing steps increases the risk that one of those steps will introduce a defect that will render the magnetic tunnel junction device 200 inoperable. As a result, yield is decreased.

Consequently, there is a need for a method of making a magnetic tunnel junction device that reduces the number of processing steps. Moreover, there exists a need for a method of making a magnetic tunnel junction device that reduces the possibility of a short circuit between the write lines and/or between the write lines and the magnetic tunnel junction stack. There is also a need for a method of making a magnetic tunnel junction device that protects the layers of magnetic material from erosion caused by chemicals used in the processing of the magnetic tunnel junction device.

### SUMMARY OF THE INVENTION

The present invention is embodied in a method of making a magnetic tunnel junction device. The magnetic tunnel junction device solves the aforementioned problems associated with chemical erosion of the plurality of layers of the magnetic material that are part of the magnetic tunnel junction stack by forming an etch stop layer made from a first electrically conductive material on the magnetic tunnel junction stack. The plurality of layers of magnetic material are positioned below the etch stop layer. The etch stop layer serves as a barrier that protects the underlying layers of magnetic material during subsequent etching steps. Chemicals contained in the etchant material, such as fluorine (F), that can chemically erode the magnetic materials, are prevented from chemically reacting with the magnetic materials by the etch stop layer.

The magnetic tunnel junction device solves the aforementioned problem of shorts between a conductor and a magnetic tunnel junction stack by forming a spacer around a portion of a magnetic tunnel junction stack. The spacer is made from a dielectric material that electrically insulates those portions of the magnetic tunnel junction stack that are in contact with the spacer. The spacer can also prevent electrical shorts between the conductors (e.g. the write lines) that are used to read data from and write data to the magnetic tunnel junction device.

Moreover, the aforementioned problems caused by additional process steps and their potential for creating defects in the magnetic tunnel junction device are solved by a dual-damascene conductor that includes a via and a top conductor that are deposited in a single process step. Consequently, fewer process steps are required to manufacture the magnetic tunnel junction device and yield can be increased because fewer process steps are required.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1a is a cross-sectional view depicting a prior magnetic tunnel junction device.

FIG. 1b is a cross-sectional view depicting erosion of layers of magnetic material in a prior magnetic tunnel junction device during an etching process.

FIG. 2 is a profile view depicting a prior magnetic tunnel junction device crossed by a pair of write lines.

FIG. 3a is a cross-sectional view depicting an ideal and an actual alignment of a via in a prior magnetic tunnel junction stack.

FIG. 3b is a cross-sectional view depicting a prior magnetic tunnel junction stack with a mis-aligned via.

FIGS. 4a and 4b are a cross-sectional views depicting an electrical short caused by the mis-aligned via of the prior magnetic tunnel junction stack of FIGS. 3a and 3b.

FIG. 5a is a flow diagram depicting a method of making a magnetic tunnel junction device.

FIG. 5b is a flow diagram depicting an alternative method of making a magnetic tunnel junction device.

FIG. 6 is a cross-sectional view depicting a magnetic tunnel junction stack.

FIG. 7a is a cross-sectional view depicting a patterning of a magnetic tunnel junction stack.

FIG. 7b is a cross-sectional view depicting an etching of a magnetic tunnel junction stack.

FIG. 8a is a cross-sectional view depicting a discrete magnetic tunnel junction stack.

FIG. 8b is a cross-sectional view depicting a forming of a spacer layer over a discrete magnetic tunnel junction stack.

FIG. 9 is a cross-sectional view depicting a discrete magnetic tunnel junction stack and a spacer.

FIG. 10a is a cross-sectional view depicting a dielectric layer formed on the discrete magnetic tunnel junction stack of FIG. 9.

FIG. 10b is a cross-sectional view depicting a planarization of the dielectric layer of FIG. 10a.

FIG. 10c and FIG. 10d are cross-sectional views depicting an etching of a first mask layer to form a self-aligned via.

FIG. 11 is a cross-sectional view depicting a second electrically conductive material formed on a dielectric layer and in a self-aligned via.

FIG. 12 is a cross-sectional view depicting a patterning and an etching of a second electrically conductive material.

FIG. 13 is a cross-sectional view depicting a magnetic tunnel junction device including a dual-damascene conductor, an etch stop layer, and an electrically non-conductive spacer.

FIG. 14 is a cross-sectional view depicting a magnetic tunnel junction device with a self-aligned via that is misaligned and layers of magnetic materials that are protected from damage due to erosion by an etch stop layer.

FIG. 15 is a top plan view of an array of magnetic tunnel junction devices.

FIG. 16 is a cross-sectional view along line A-A of FIG. 15.

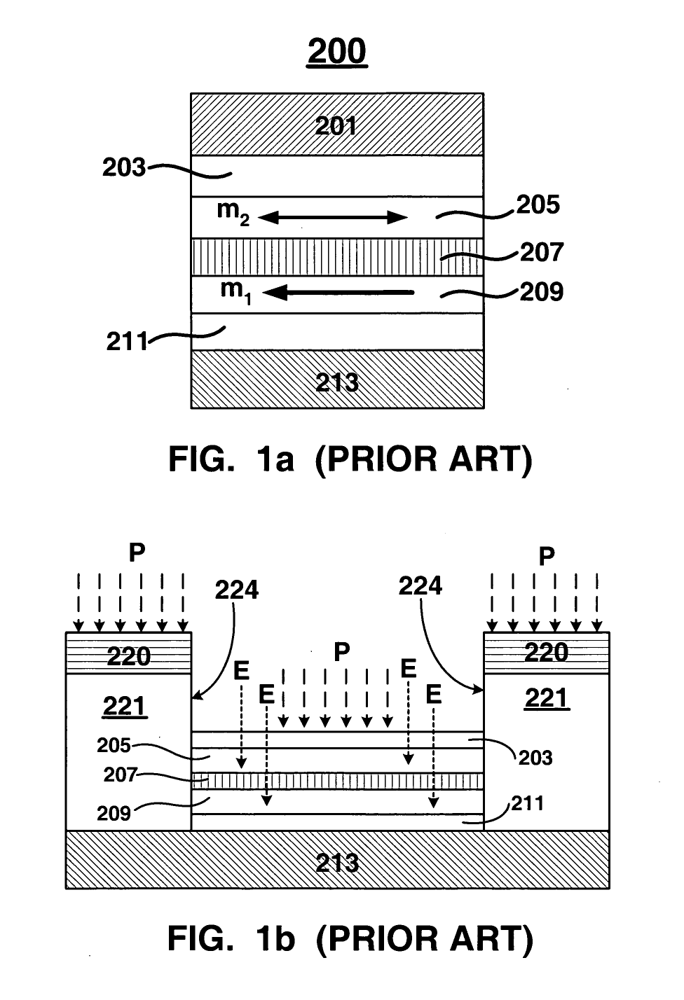

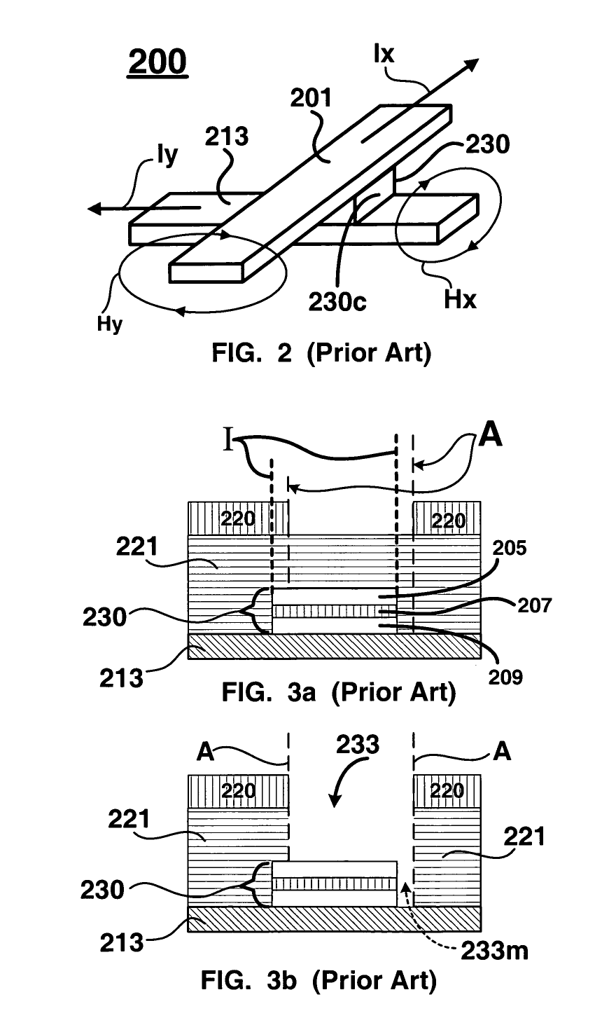

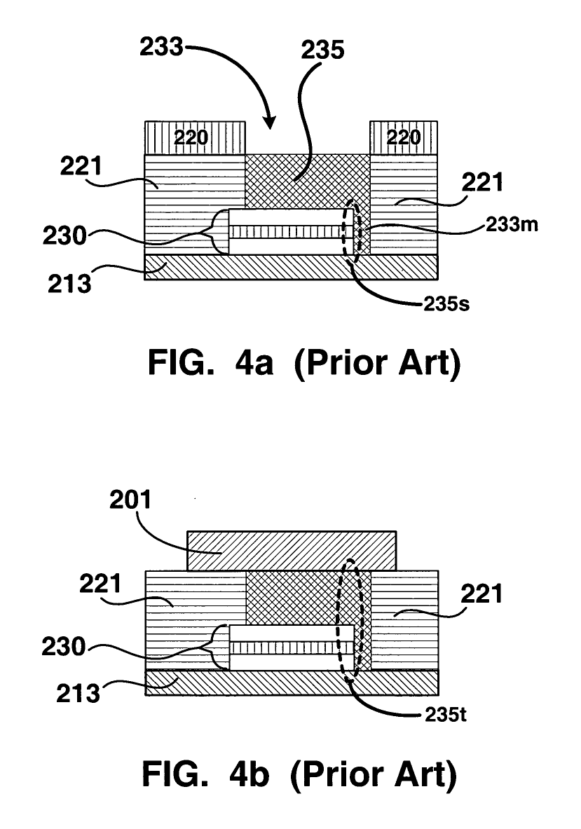

### DETAILED DESCRIPTION

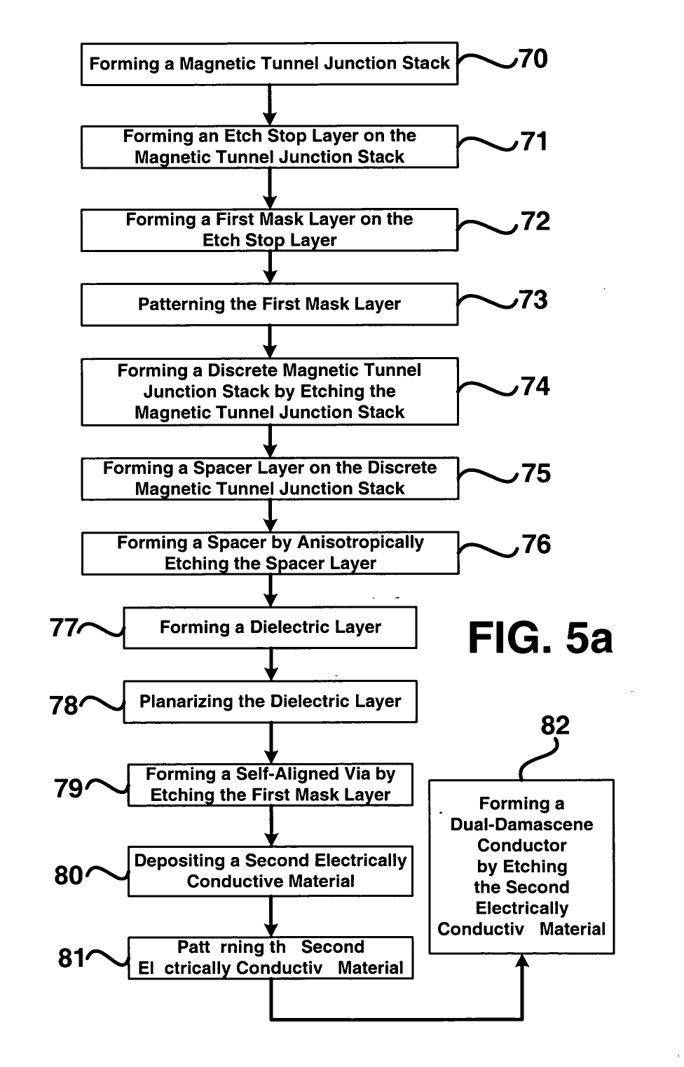

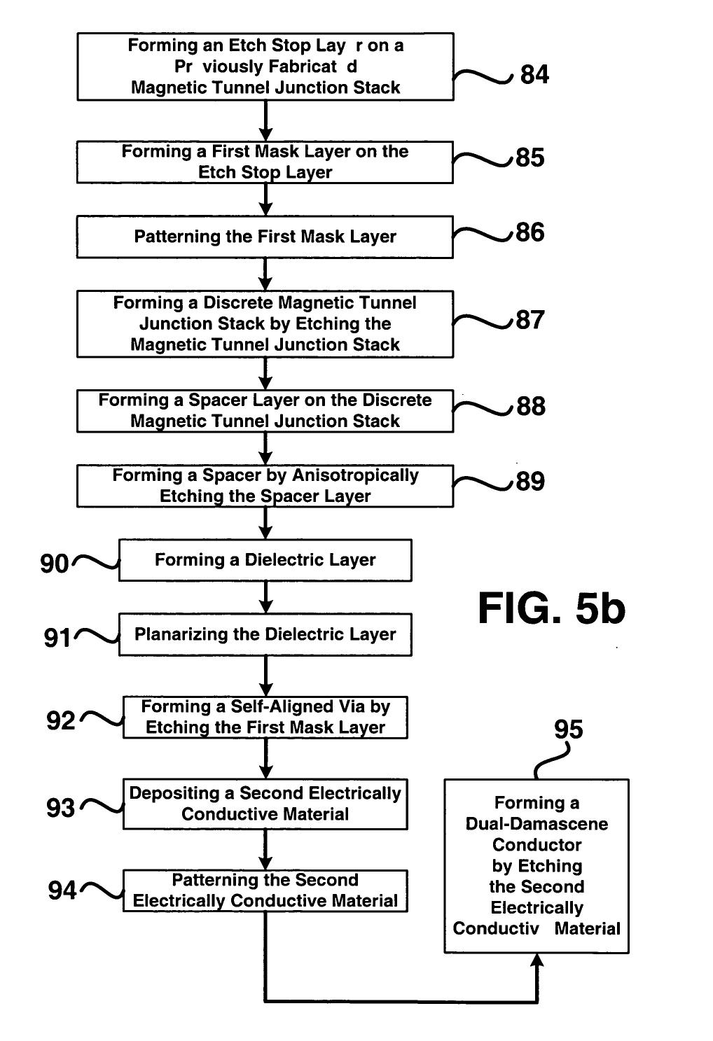

As shown in the drawings for purpose of illustration, the present invention is embodied in a method of making a magnetic tunnel junction device. In FIG. 5a, a first embodiment of the method includes forming 70 a magnetic tunnel junction stack, forming 71 an etch stop layer on the magnetic tunnel junction stack, forming 72 a first mask layer on the etch stop layer, and patterning 73 the first mask layer. A discrete magnetic tunnel junction stack is formed 74 by etching the magnetic tunnel junction stack, then a spacer layer is formed 75 on the discrete magnetic tunnel junction stack. The spacer layer is anisotropically etched to form 76 a spacer. A dielectric layer is formed 77 on the discrete magnetic tunnel junction stack and the spacer followed by a planarizing 78 of the dielectric layer. A self-aligned via is formed 79 by etching the first mask layer. A second electrically conductive material is deposited 80 in the self-aligned via and on the dielectric layer. The second electrically conductive material is then patterned 81. A dual-damascene conductor is formed 82 by etching the second electrically conductive material.

In FIG. 5b, a second embodiment of the method includes forming 84 an etch stop layer on a previously formed magnetic tunnel junction stack. A first mask layer is formed 85 on the etch stop layer followed by a patterning 86 the first mask layer. A discrete magnetic tunnel junction stack is formed 87 by etching the magnetic tunnel junction stack. A spacer layer is formed 88 on the discrete magnetic tunnel junction stack. The spacer layer is then anisotropically etched to form 89 a spacer. A dielectric layer is formed 90 on the discrete magnetic tunnel junction stack and the spacer followed by a planarizing 91 of the dielectric layer. A self-aligned via is formed 92 by etching the first mask layer. A second electrically conductive material is deposited 93 in the self-aligned via and on the dielectric layer. The second electrically conductive material is then patterned 94. A dual-damascene conductor is formed 95 by etching the second electrically conductive material.

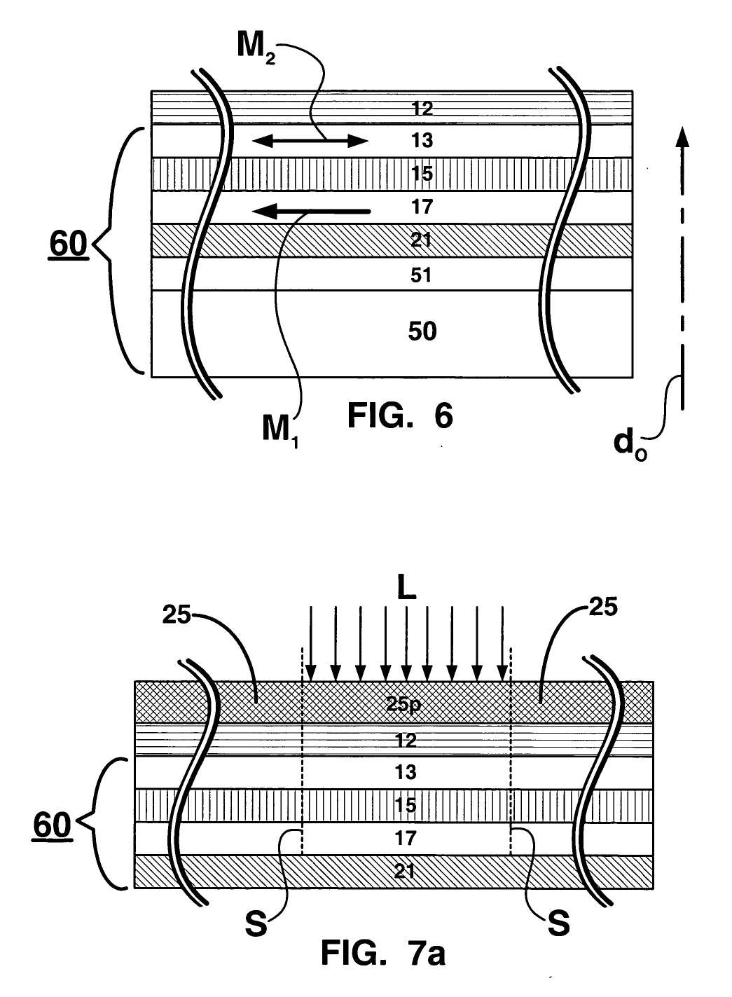

In FIG. 6 and referring to the above mentioned first embodiment of the method as depicted in FIG. 5a, at a stage 70, a magnetic tunnel junction stack 60 is formed. The magnetic tunnel junction stack 60 includes a plurality of layers of thin film materials that are well known in the MRAM art. Those layers include but are not limited to a substrate 50, a dielectric layer 51, an electrically conductive material 21, a reference layer 17, a tunnel barrier layer 15, and a data layer 13.

The substrate 50 can be a semiconductor material such as single crystal silicon (Si) or a silicon (Si) wafer, for example. The dielectric layer 51 can be deposited on the substrate 50 or grown on the substrate 50. For example, a surface of a silicon wafer can be oxidized to grow a layer of silicon oxide (SiO₂) for the dielectric layer 51. The electrically conductive material 21 can be a bottom conductor that serves as one of the write lines and can be made from a material including but not limited to aluminum (Al) and tungsten (W), for example. The reference layer 17 can be a thin film layer of a magnetic material such as nickel iron (NiFe) or alloys of those materials, for example. The tunnel barrier layer 15 can be a thin film layer of a dielectric material such as aluminum oxide (Al₂O₃) or silicon oxide (SiO₂) for a TMR device or a thin film layer of an electrically conductive material such as copper (Cu) for a GMR device, for example. The data layer 13 can be a thin film layer of a magnetic material such as nickel iron cobalt (NiFeCo) or alloys of those materials, for example. The above mentioned layers are referred to as thin film layers because most of the layers of material that are used to fabricate a magnetic tunnel junction device have thicknesses on the order of about 15.0 nm or less.

In FIG. 6, the plurality of layers of thin film materials are deposited or otherwise formed on the substrate 50 in a deposition order d_{O}. For purposes of illustration, other layers that can be included in a magnetic tunnel junction device, such as cap layers, seed layers, pinning films, artificial anti-ferromagnetic layers, and the like, are not depicted in FIG. 6. However, those layers can be included in the magnetic tunnel junction stack 60. Deposition processes that are well known in the microelectronics art can be used to deposit the layers in the magnetic tunnel junction stack 60. For example, physical vapor deposition (PVD), plasma enhanced chemical vapor deposition (PECVD), and sputtering are processes that can be used to form the aforementioned layers. PVD can include thermal evaporation and sputtering.

At a stage 71, an etch stop layer 12 is formed on the magnetic tunnel junction stack 60. Although the etch stop layer 12 is depicted in contact with the data layer 13, the method of the present invention includes forming the etch stop layer 12 on any suitable layer positioned at a top portion of the magnetic tunnel junction stack 60 so that during an etching process that will be described below, the underlying layers of magnetic material in the magnetic tunnel junction stack 60 are not chemically eroded by chemicals in an etchant material used in the etching process. Accordingly, the etch stop layer 12 serves as a barrier that prevents the chemical erosion of the plurality of layers of a magnetic material positioned below the etch stop layer 12 in the magnetic tunnel junction stack 60.

Consequently, after the etching process, the layers of thin film materials, particularly those layers that are made from a magnetic material, are not damaged due to chemical erosion. In FIG. 6, the data layer 13 is positioned at the top portion of the magnetic tunnel junction stack 60 because the data layer 13 was the last layer to be deposited in the deposition order d_{O}. However, the etch stop layer 12 will be in contact with whatever layer in the magnetic tunnel junction stack 60 that precedes the etch stop layer 12 in the deposition order d_{O}. Suitable materials for the first electrically conductive material for the etch stop layer 12 include but are not limited to aluminum (Al) and alloys of aluminum.

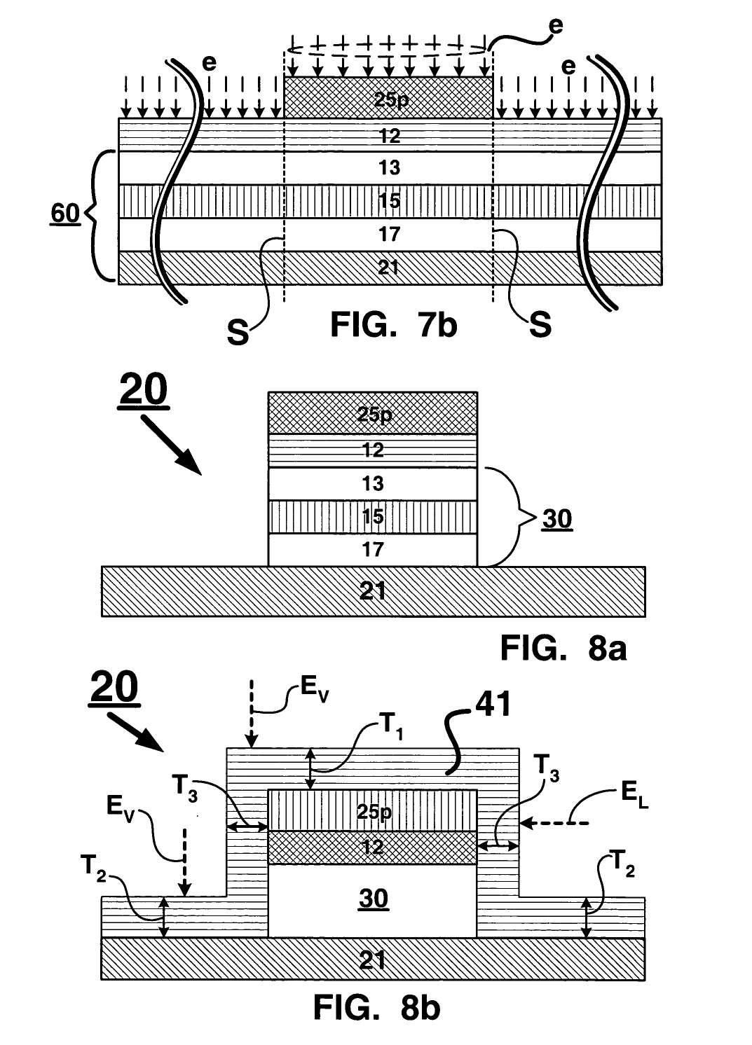

In FIG. 7a, at a stage 72, a first mask layer 25 is formed on the etch stop layer 12. For example, the first mask layer 25 can be a photoresist material that is deposited on the etch stop layer 12. At a stage 73, the first mask layer 25 is patterned to form a predetermined pattern in the first mask layer 25. For instance, the photoresist material can be exposed to light L, using photolithographic processes that are well known in the microelectronics art to cause the exposed portion to harden or otherwise alter the properties of the material for the first mask layer 25 so that exposed portion forms an etch resistant pattern or etch mask.

Accordingly, in FIG. 7a, a patterned portion 25p of the first mask layer 25 that is exposed to the light L forms an etch mask that will be used during an etch process to form a discrete stack out of the magnetic tunnel junction stack 60 as denoted by the dashed lines S. After the exposure to the light L and prior to the etching process, the first mask layer 25 is developed to remove those portions not exposed to the light L so that the patterned portion 25p of the of the first mask layer 25 remains on the magnetic tunnel junction stack 60 as depicted in FIG. 7b. Hereinafter, the patterned portion 25p of the of the first mask layer 25 will be denoted as the first mask layer 25p.

In FIG. 7b, at a stage 74, the magnetic tunnel junction stack 60 is etched e to remove those portions of the magnetic tunnel junction stack 60 that are not covered by the first mask layer 25p. As a result, in FIG. 8a, a discrete magnetic tunnel junction stack 20 is formed substantially along the dashed lines S of FIGS. 7a and 7b. The layers (13, 15, 17) of the discrete magnetic tunnel junction stack 20 that are positioned under the etch stop layer 12, unless otherwise noted, will be collectively denoted as the layers 30.

An etch process such as a wet etch or a plasma etch can be used to form the discrete magnetic tunnel junction stack 20, for example. The etch material can be selected such that it selectively etches the layers (13, 15, 17) of the magnetic tunnel junction stack 60 but is not selective to the bottom conductor 21 so that the bottom conductor 21 serves as an etch stop. Alternatively, the etch process can be controlled to halt the etching at a predetermined time. Although not shown, the etch process can etch through the bottom conductor 21.

In FIG. 8b, at a stage 75, a spacer layer 41 is formed on the discrete magnetic tunnel junction stack 20. The spacer layer 41 is made from an electrically non-conductive material. Suitable materials for the spacer layer 41 include but are not limited to silicon oxide (SiO₂) and silicon nitride (Si₃N₄). Preferably, the spacer layer 41 is conformally deposited on the discrete magnetic tunnel junction stack 20 so that a thickness of the spacer layer 41 is substantially uniform on all sides of the discrete magnetic tunnel junction stack 20 that are covered by the spacer layer 41. For example, thicknesses (T₁, T₂, and T₃) on top, bottom, and side portions of the discrete magnetic tunnel junction stack 20 are substantially equal to one another such that after the conformal deposition T₁≈T₂ ≈T₃. That is, the lateral growth rate of the material for the spacer layer 41 is substantially equal to the vertical growth rate of the material resulting in horizontal (T₁, T₂) and vertical (T₃) sidewall thicknesses that are substantially equal to one another.

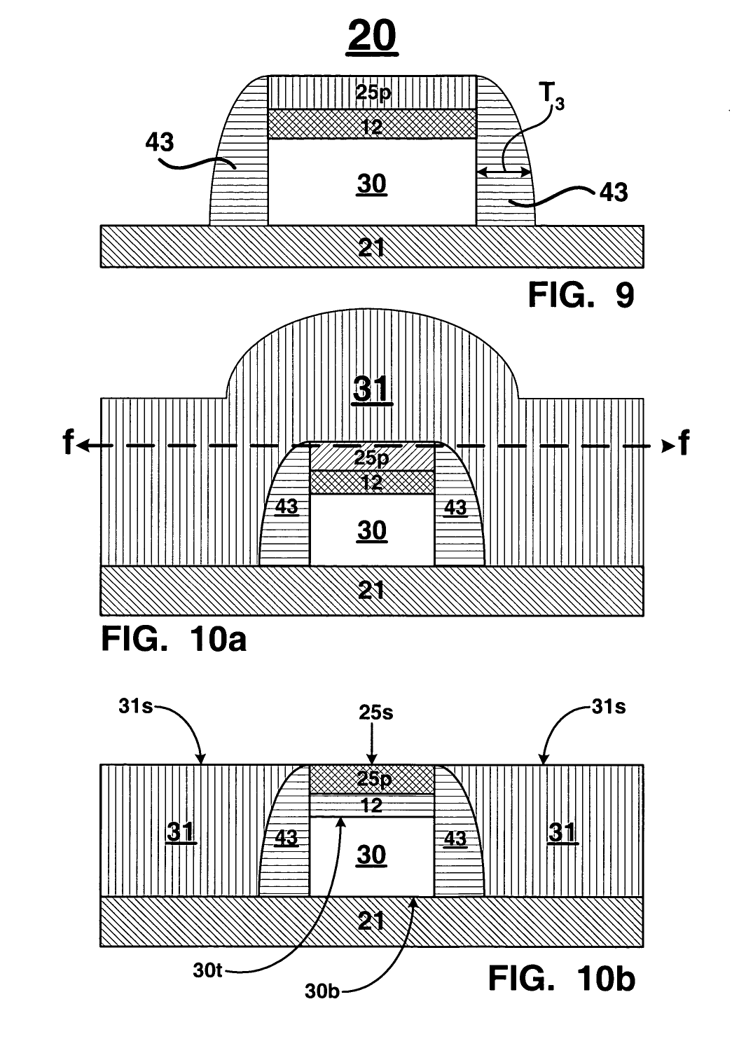

In FIG. 9, at a stage 76, the spacer layer 41 is anisotropically etched to form a spacer 43 that is in contact with a portion of the discrete magnetic tunnel junction stack 20. Preferably, the etching of the spacer layer 41 is accomplished using an anisotropic etching process that includes an etch material that has a faster etch rate in a preferred etch direction E_{V} (see FIG. 8b). For example, a reactive ion etching (RIE) process can be used to etch the spacer layer 41.

In FIG. 8b, the preferred etch direction E_{V} is in a substantially vertical direction; whereas, an non-preferred etch direction E_{L} is in a substantially lateral direction. As a result, the anisotropic etching process etches the spacer layer 41 faster in the preferred etch direction E_{V} so that after the etch process, the material of the spacer layer 41 along the horizontal thicknesses (T₁, T₂) is removed and the material along vertical thickness T₃ remains and forms the spacer 43. Deposition processes that are well known in the microelectronics arts, such as chemical vapor deposition (CVD), plasma enhanced chemical vapor deposition (PECVD), and atomic layer deposition (ALD) can be used to deposit the spacer layer 41 on the discrete magnetic tunnel junction stack 20 and the bottom conductor 21.

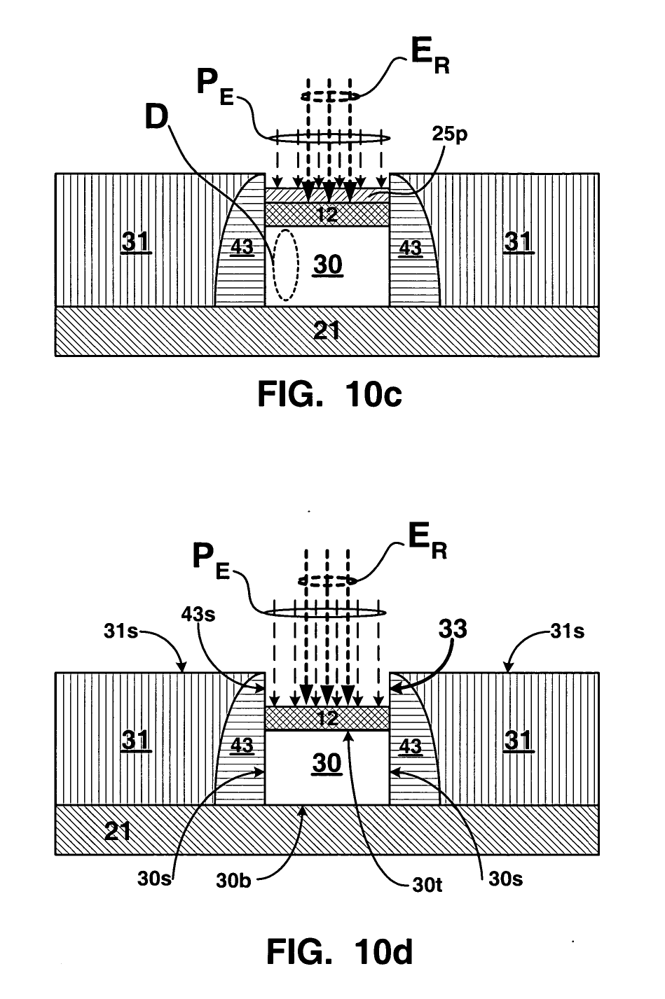

In FIG. 10a, at a stage 77, a dielectric layer 31 is formed over the discrete magnetic tunnel junction stack 20 and the spacer 43. Suitable materials for the dielectric material 31 include but are not limited to silicon oxide (SiO₂) and silicon nitride (Si₃N₄). The dielectric material 31 completely covers the discrete magnetic tunnel junction stack 20 and the spacer 43. In FIG. 10b, at a stage 78, the dielectric layer 31 is planarized to form a substantially planar surface 31s. Preferably, the dielectric layer 31 is planarized along a line f-f (see FIG. 10a). A process including but not limited to chemical mechanical planarization (CMP) can be used to planarize the dielectric layer 31. The line f-f passes through a portion of the first mask layer 25p so that after the planarization of the dielectric layer 31 the first mask layer 25p has a substantially planar surface 25s that is substantially flush with the substantially planar surface 31s and the substantially planar surface 25s is exposed for a subsequent etching step as will be described below.

In FIG. 10c, at a stage 79, a remaining portion the first mask layer 25p is etched by an etch process P_{E} that selectively dissolves (i.e. removes) the first mask layer 25p. In FIG. 10d, the etching process P_{E} is continued until the first mask layer 25p is completely dissolved and a self-aligned via 33 is formed. The self-aligned via 33 extends all the way to the etch stop layer 12. After the etching process P_{E}, the layers 30 include a top portion 30t that is positioned below the etch stop layer 12, side portions 30s that are in contact with the spacer 43, and a bottom portion 30b that is in contact with the bottom conductor 21.

The etch material used in the etch process P_{E} is not selective to the material of the etch stop layer 12 such that the etch stop layer 12 serves as a penetration barrier (see dashed arrows E_{R}) that protects the layers of magnetic material in the layers 30 that are positioned below the etch stop layer 12 from damage D that can be caused by chemical erosion. Moreover, the etch material used in the etch process P_{E} is not selective to the material of the spacer 43 so that the self-aligned via 33 is partially defined by sidewall surfaces 43s of the spacers 43.

The etch process P_{E} can be a plasma etch process or a wet etch process and an etchant material used in the etch process P_{E} can include the chemical fluorine (F). Fluorine (F) can chemically react with and erode the layers magnetic materials in the layers 30. For example, it is well understood in the MRAM art that a fluorine (F) based plasma etch can erode magnetic materials including but not limited to nickel (Ni), iron (Fe) and cobalt (Co). Because the data layer 13 and the reference layer 17 can include one or more of those materials and alloys of those materials, the etch stop layer 12 prevents chemical erosion of the nickel (Ni), iron (Fe), and cobalt (Co). The etch material can be a fluorine containing gas including but not limited to CF₄, CHF₃, C₄F₈, and SF₆. Additionally, for a plasma etch process, the etch material (i.e. the etch gas) can include oxygen (O₂) and fluorine (F) alone or in combination with other chemical compounds as described above.

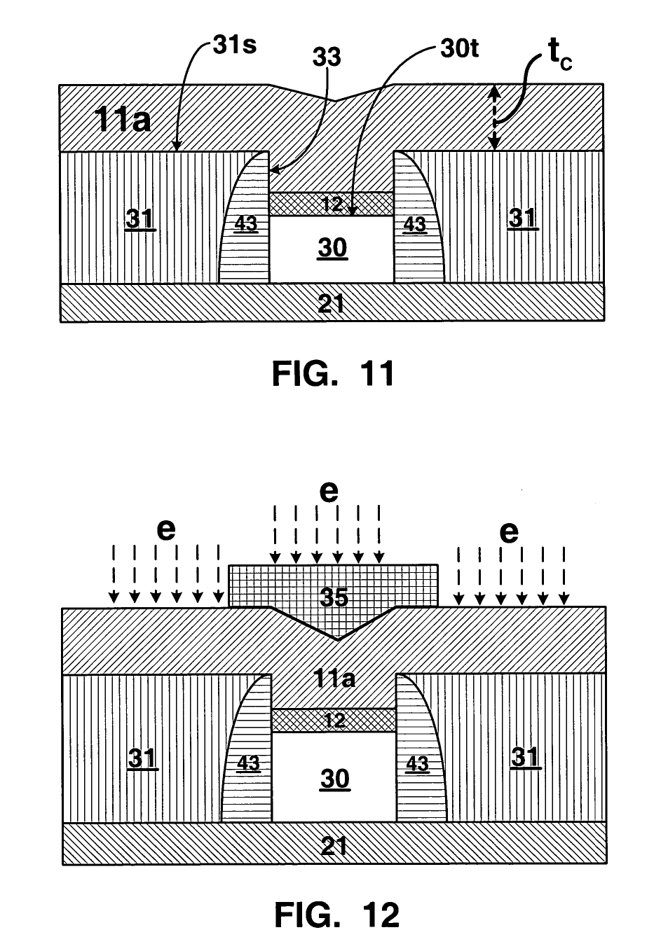

In FIG. 11, at a stage 80, a second electrically conductive material 11a is deposited on the dielectric layer 31 and in the self-aligned via 33. Preferably, the deposition continues until the second electrically conductive material 11a completely fills the self-aligned via 33 (i.e. the self-aligned via 33 is completely filled in) and the second electrically conductive material 11a extends outward of the upper surface 31s by a predetermined distance t_{c} (i.e. by a thickness t_{c}). The second electrically conductive material 11a is in contact with the etch stop layer 12.

A process including but not limited to physical vapor deposition (PVD), sputtering, or plasma enhanced chemical vapor deposition (PECVD) can be used to deposit the second electrically conductive material 11a, for example. Suitable materials for the second electrically conductive material 11a include but are not limited to aluminum (Al), alloys of aluminum, tungsten (W), alloys of tungsten, copper (Cu), and alloys of copper. If copper (Cu) is used for the second electrically conductive material 11a, then a process such as electroplating can be used for a deposition of the copper. Suitable materials for the bottom conductor 21 include but are not limited to the aforementioned materials for the second electrically conductive material 11a.

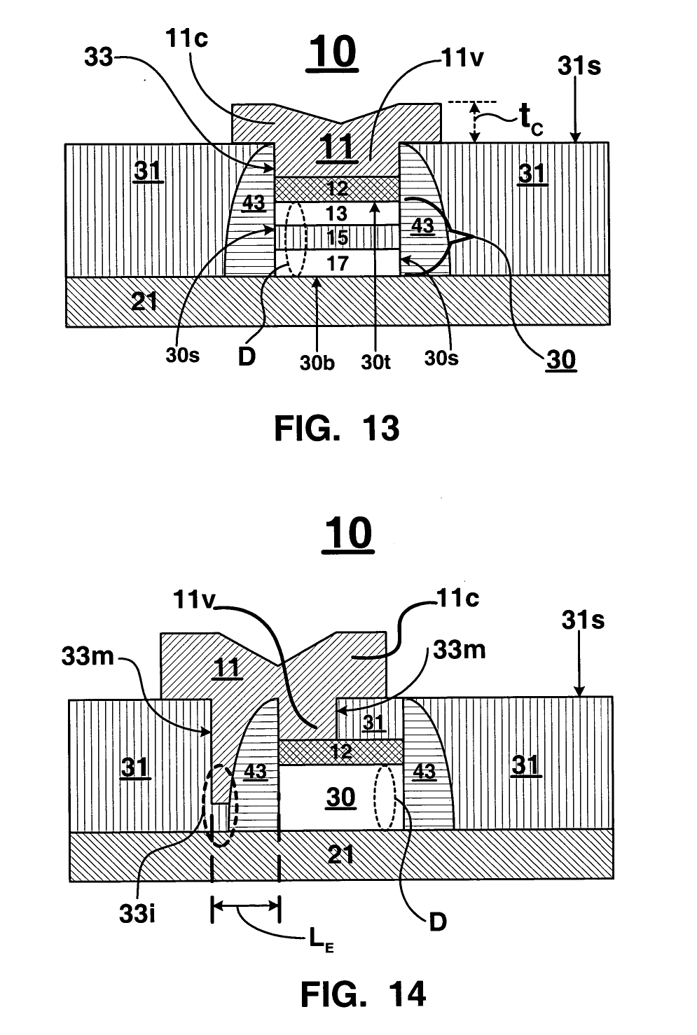

In FIG. 12, at a stage 81, the second electrically conductive material 11a is patterned. For instance, a photolithographic process and a photoresist material 35 can be used to pattern the second electrically conductive material 11a. After the pattern is developed, a portion of the photoresist material 35 remains and serves as an etch mask. At a stage 82, the second electrically conductive material 11a is etched e to define a dual-damascene conductor 11 (see FIG. 13). The dual-damascene conductor 11 is in contact with the etch stop layer 12.

In FIG. 13, the dual-damascene conductor 11 includes a first portion 11v and a second portion 11c. The first portion 11v is a via that is positioned in the self-aligned via 33. The first portion 11v completely fills the self-aligned via 33 and is in contact with the etch stop layer 12. The second portion 11c is a top conductor that is in contact with the substantially planar surface 31s of the first dielectric material 31 and extends outward of the substantially planar surface 31s. The second portion 11c can extend outward of the upper surface 31s by the predetermined distance t_{C}. Another advantage of the method is that the first and second portions (11v, 11c) of the dual-damascene conductor 11 are homogeneously formed with each other in one deposition step instead of two or more process steps, thereby reducing the number of process steps and a potential decrease in yield. The dual-damascene conductor 11 can be a top electrode or conductor of the magnetic tunnel junction device 10. Collectively, the dual-damascene conductor 11 and the bottom conductor 21 can be referred to as write lines.

In FIG. 13, a magnetic tunnel junction device 10 is formed and includes the dual-damascene conductor 11, the bottom conductor 21, the reference layer 17, the tunnel barrier layer 15, the data layer 13, and the etch stop layer 12. The reference layer 17 is in electrical communication with the bottom conductor 21 and the data layer 13 is in contact with the etch stop layer 12. The electrical communication between the bottom conductor 21 and whatever layer is at the bottom portion 30b can be by a direct connection or through an intermediate structure such as a via or the like. In FIG. 13, the bottom conductor 21 is in contact with the bottom portion 30b; however, the bottom conductor 21 need not be in direct contact with the bottom portion 30b. The dual-damascene conductor 11 is in electrical communication with the top portion 30t through the etch stop layer 12 (i.e. the via 11v is in contact with the etch stop layer 12). The order of the layers 30 (e.g. thin film layers 17, 15, 13) need not be as depicted in FIGS. 7a, 7b, 8a, and 13, for example, the data layer 13 can be positioned at the bottom portion 30b, the reference layer 17 can be positioned at the top portion 30t, and the tunnel barrier layer 15 can be positioned between the data and reference layers (13, 17).

Accordingly, in FIG. 13, the bottom conductor 21 is in electrical communication with a bottom portion 30b of the layers 30 and the etch stop layer 12 is in contact with a top portion 30t of the layers 30. The data and reference layers (13, 17), the tunnel barrier layer 15, and any of the other layers that comprise the layers in 30 (e.g. cap layers, seed layers, etc.) will be positioned between the bottom conductor 21 and the etch stop layer 12 in whatever logical order is dictated by the magnetic tunnel junction topology.

In FIG. 14, another advantage of the method is that a misalignment of the self-aligned via 33 relative to the layers 30 of the discrete magnetic tunnel junction stack 20 does not automatically result in a short circuit or a defect in the magnetic tunnel junction device 10. Because the process used to fabricate the magnetic tunnel junction device 10 are not perfect, misalignment errors caused by the lithographic processes and the etching processes, just to name a few, usually result in the self-aligned via 33 being misaligned relative to the layers 30. In FIG. 14, a self-aligned via 33m is misaligned relative to the layers 30. After the second electrically conductive material 11a is deposited in the self-aligned via 33m, the misalignment results in a region 33i between the spacer 43 and the dielectric layer 31 that prevents the first portion 11v (i.e. the via) from electrically communicating with the layers 30 and/or the bottom conductor 21.

In FIG. 14, after the dual-damascene conductor 11 is formed, the dual-damascene conductor 11 is not in electrical communication with the bottom conductor 21 and/or the side portions 30s of the layers 30 because the spacer 43 provides a lateral error margin L_{E} that allows the first portion 11v to be misaligned relative to the layers 30. Consequently, the first portion 11v does not extend all the way to the bottom conductor 21 so that the dual-damascene conductor 11 is not shorted to the bottom conductor 21. Furthermore, the lateral error margin L_{E} provided by the spacer 43 prevents the first portion 11v from connecting with the side portions 30s of the layers 30.

In FIG. 6 and referring to the above mentioned second embodiment of FIG. 5b, the magnetic tunnel junction device 10 can be fabricated as was described above in reference to FIGS. 6 through 14. However, instead of forming the magnetic tunnel junction stack 60 as depicted in FIG. 6, an already fabricated magnetic tunnel junction stack 60 is provided and the etch stop layer 12 is then formed on the previously fabricated magnetic tunnel junction stack 60. Accordingly, the stage 70 as depicted in FIG. 5a, has been previously performed to fabricate the magnetic tunnel junction stack 60 and the etch stop layer 12 is then formed at a stage 84 on the last layer to be formed on the magnetic tunnel junction stack 60 in the deposition order d_{O}. The remaining process steps for forming the magnetic tunnel junction device 10 can be carried out according to the steps of FIG. 5b (i.e. stages 84 through 95) and as depicted in FIGS. 7a through 14.

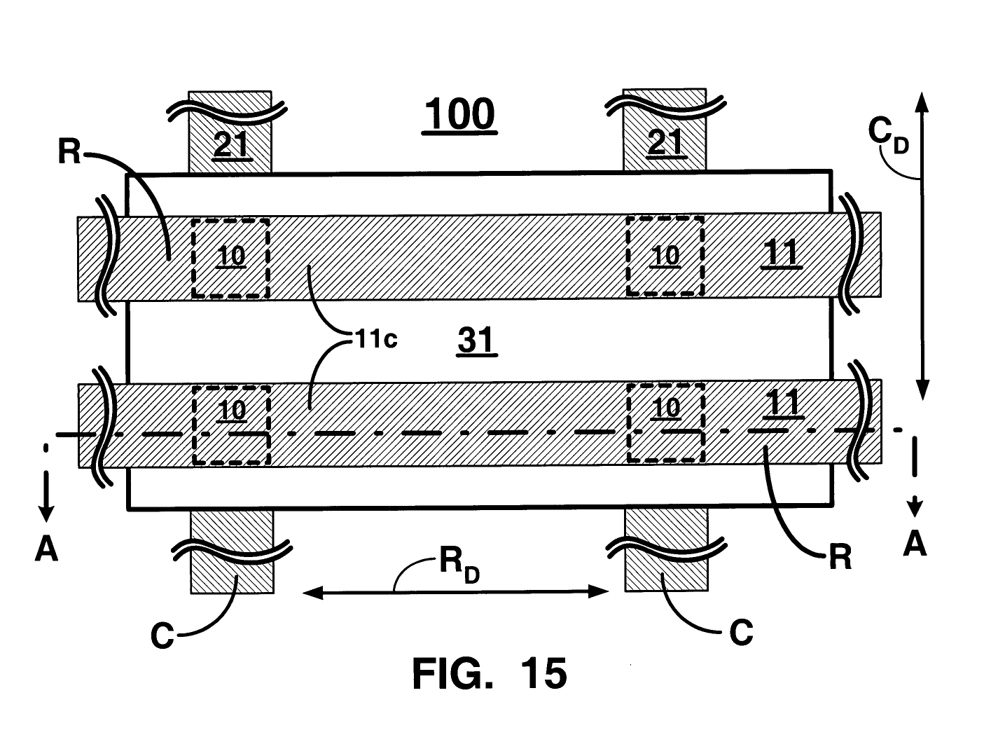

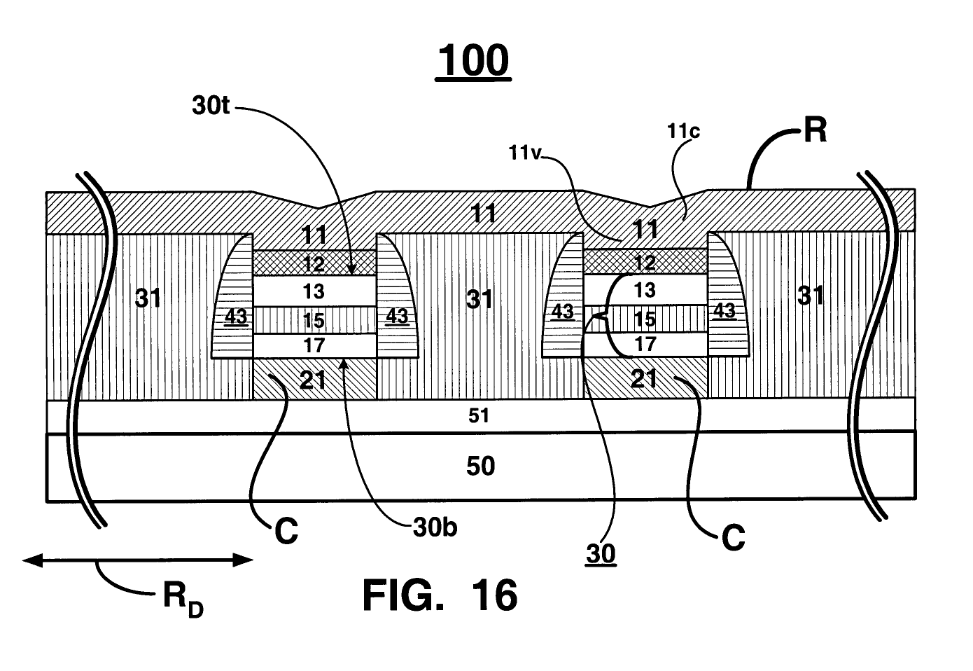

In FIG. 15, a plurality of the magnetic tunnel junction devices 10 can be configured in an array 100. The array 100 can be a MRAM used to store and retrieve data written to the plurality of magnetic tunnel junction devices 10. The bottom conductor 21 can be a column conductor C that is aligned with a column direction C_{D} and the dual-damascene conductor 11 can be a row conductor R that is aligned with a row direction R_{D}. Alternatively, although not depicted in FIG. 16, one of ordinary skill in the art will understand that the bottom conductor 21 can be the row conductor R and the dual-damascene conductor 11 can be the column conductor C. The magnetic tunnel junction devices 10 are positioned between an intersection of the row and column conductors (R, C) as depicted by the dashed lines 10.

In FIG. 15, the second portion 11c (i.e. the top conductor) of the dual-damascene conductor 11 is depicted aligned with the row direction R_{D}; however, the first portion 11v (i.e. the via) is not visible in the view depicted in FIG. 15. Typically, the row R and column C conductors are positioned in orthogonal relation to each other so that they cross each of the magnetic tunnel junction devices 10 at substantially right angles to each other. Accordingly, the row and column conductors (R, C) define the rows and columns of the array 100 and the magnetic tunnel junction devices 10 are positioned at an intersection of the rows R and the columns C of the array 100. The alterable orientation of magnetization M₂ (see FIG. 6) in the data layer 13 is rotated (i.e. flipped) by passing currents (not shown) of sufficient magnitude through a selected row and column conductor (R, C) so that magnetic fields generated by those currents cooperatively combine to flip the alterable orientation of magnetization M₂.

In FIG. 16, a cross-sectional view of the array 100 along a line A-A of FIG. 15 (i.e. along the row direction R_{D}) depicts dual-damascene conductor 11 running along the row direction R_{D} with the first portion 11v in contact with the etch stop layer 12 of the magnetic tunnel junction devices 10 in the row R. Similarly, the column conductors C are electrical communication with the reference layers 17 in their respective columns. The electrical communication can be by direct contact with the reference layers 17 or by an intermediate structure such as a via (not shown) or the like. Although not depicted in FIGS. 15 and 16, the self-aligned via 33 can be misaligned with the layers 30 as described above in reference to FIG. 14.

Although several embodiments of the present invention have been disclosed and illustrated, the invention is not limited to the specific forms or arrangements of parts so described and illustrated. The invention is only limited by the claims.

1. A method of making a magnetic tunnel junction device, comprising:
forming a magnetic tunnel junction stack;
forming an etch stop layer on the magnetic tunnel junction stack, the etch stop layer comprising a first electrically conductive material;
forming a first mask layer on the etch stop layer;
patterning the first mask layer;
forming a discrete magnetic tunnel junction stack by etching the magnetic tunnel junction stack;
forming a spacer layer on the discrete magnetic tunnel junction stack, the spacer layer comprising an electrically non-conductive material;
forming a spacer by anisotropically etching the spacer layer;
forming a dielectric layer over the discrete magnetic tunnel junction stack and the spacer;
planarizing the dielectric layer until the dielectric layer and the first mask layer form a substantially planar surface;
forming a self-aligned via by etching away the first mask layer;
depositing a second electrically conductive material on the dielectric layer and in the self-aligned via;
patterning the second electrically conductive material; and
forming a dual-damascene conductor by etching the second electrically conductive material.

2. The method as set forth in claim 1, wherein the etching away the first mask layer comprises a plasma etch using an etch material comprising a gas containing fluorine.

3. The method as set forth in claim 2, wherein the etch material further includes oxygen.

4. The method as set forth in claim 1, wherein the etching of the first mask layer to form the self-aligned via comprises a wet etch using an etchant material including fluorine.

5. The method as set forth in claim 1, wherein the depositing of the second electrically conductive material is continued until the second electrically conductive material completely fills in the self-aligned via and extends outward of the substantially planar surface by a predetermined distance.

6. The method as set forth in claim 1, wherein the etching the first mask layer is continued until the first mask layer is completely dissolved and the self-aligned via extends to the etch stop layer.

7. The method as set forth in claim 1, wherein the spacer layer is conformally deposited on the discrete magnetic tunnel junction stack.

8. The method as set forth in claim 1, wherein the spacer layer comprises a material selected from the group consisting of silicon oxide and silicon nitride.

9. The method as set forth in claim 1, wherein the anisotropically etching the spacer layer comprises a reactive ion etch.

10. The method as set forth in claim 1, wherein after the forming of the self-aligned via, the discrete magnetic tunnel junction stack and the self-aligned via are not aligned relative to each other.

11. A method of making a magnetic tunnel junction device from a previously fabricated magnetic tunnel junction stack, comprising:
forming an etch stop layer on the magnetic tunnel junction stack, the etch stop layer comprising a first electrically conductive material;
forming a first mask layer on the etch stop layer;
patterning the first mask layer;
forming a discrete magnetic tunnel junction stack by etching the magnetic tunnel junction stack;
forming a spacer layer on the discrete magnetic tunnel junction stack, the spacer layer comprising an electrically non-conductive material;
forming a spacer by anisotropically etching the spacer layer;
forming a dielectric layer over the discrete magnetic tunnel junction stack and the spacer;
planarizing the dielectric layer until the dielectric layer and the first mask layer form a substantially planar surface;
forming a self-aligned via by etching away the first mask layer;
depositing a second electrically conductive material on the dielectric layer and in the self-aligned via;
patterning the second electrically conductive material; and
forming a dual-damascene conductor by etching the second electrically conductive material.

12. The method as set forth in claim 11, wherein the etching away the first mask layer comprises a plasma etch using an etch material comprising a gas containing fluorine.

13. The method as set forth in claim 12, wherein the etch material further includes oxygen.

14. The method as set forth in claim 11, wherein the etching of the first mask layer to form the self-aligned via comprises a wet etch using an etch material including fluorine.

15. The method as set forth in claim 11, wherein the depositing of the second electrically conductive material is continued until the second electrically conductive material completely fills in the self-aligned via and extends outward of the substantially planar surface by a predetermined distance.

16. The method as set forth in claim 11, wherein the etching the first mask layer is continued until the first mask layer is completely dissolved and the self-aligned via extends to the etch stop layer.

17. The method as set forth in claim 11, wherein the spacer layer is conformally deposited on the discrete magnetic tunnel junction stack.

18. The method as set forth in claim 11, wherein the spacer layer comprises a material selected from the group consisting of silicon oxide and silicon nitride.

19. The method as set forth in claim 11, wherein the anisotropically etching the spacer layer comprises a reactive ion etch.

20. The method as set forth in claim 11, wherein after the forming of the self-aligned via, the discrete magnetic tunnel junction stack and the self-aligned via are not aligned relative to each other.

21. A magnetic tunnel junction device, comprising:
a discrete magnetic tunnel junction stack including a top portion, a bottom portion, and a side portion;
an etch stop layer of a first electrically conductive material, the etch stop layer is in contact with the top portion;
an electrically non-conductive spacer in contact with the side portion;
a dielectric layer surrounding the spacer;
a self-aligned via positioned between the spacer and extending to the top portion;
a bottom conductor in electrical communication with the bottom portion; and
a dual-damascene conductor including a top conductor and a via, the via is in contact with the etch stop layer and is positioned in the self-aligned via, and the top conductor and the via are homogeneously formed with each other.

22. The magnetic tunnel junction device as set forth in claim 21, wherein the first electrically conductive material for the etch stop layer is a material selected from the group consisting of aluminum and alloys of aluminum.

23. The magnetic tunnel junction device as set forth in claim 21, wherein the dual-damascene conductor is made from a material selected from the group consisting of aluminum, alloys of aluminum, tungsten, alloys of tungsten, copper, and alloys of copper.

24. The magnetic tunnel junction device as set forth in claim 21 and further comprising:
a plurality of the magnetic tunnel devices positioned in a plurality of rows and a plurality of columns of an array;
a plurality of row conductors that are aligned with a row direction of the array; and
a plurality of column conductors that are aligned with a column direction of the array,
each of the plurality of the magnetic tunnel junction devices is positioned between an intersection of one of the row conductors with one of the column conductors,
wherein the plurality of row conductors comprises a selected one of the dual-damascene conductor or the bottom conductor, and
wherein the plurality of column conductors comprises a selected one of the dual-damascene conductor or the bottom conductor.

25. The magnetic tunnel junction device as set forth in claim 24, wherein the array is a MRAM array.

26. A magnetic tunnel junction device, comprising:
a discrete magnetic tunnel junction stack including a plurality of thin film layers that include a data layer, a reference layer, and a tunnel barrier layer positioned between the data layer and the reference layer;
the plurality of thin film layers including a top portion, a bottom portion, and a side portion;
an etch stop layer of a first electrically conductive material, the etch stop layer is in contact with the top portion;
an electrically non-conductive spacer in contact with the side portion;
a dielectric layer surrounding the spacer;
a self-aligned via positioned between the spacer and extending to the top portion;
a bottom conductor in electrical communication with the bottom portion; and
a dual-damascene conductor including a top conductor and a via, the via is in contact with the etch stop layer and is positioned in the self-aligned via, and the top conductor and the via are homogeneously formed with each other.

27. The magnetic tunnel junction device as set forth in claim 26, wherein the first electrically conductive material for the etch stop layer is a material selected from the group consisting of aluminum and alloys of aluminum.

28. The magnetic tunnel junction device as set forth in claim 26, wherein the dual-damascene conductor is made from a material selected from the group consisting of aluminum, alloys of aluminum, tungsten, alloys of tungsten, copper, and alloys of copper.

29. The magnetic tunnel junction device as set forth in claim 26, wherein the data layer is positioned at the top portion and the data layer is in contact with the etch stop layer.

30. The magnetic tunnel junction device as set forth in claim 26, wherein the reference layer is positioned at the top portion and the reference layer is in contact with the etch stop layer.

31. The magnetic tunnel junction device as set forth in claim 26, wherein the tunnel barrier layer is made from a dielectric material.

32. The magnetic tunnel junction device as set forth in claim 26 and further comprising:
a plurality of the magnetic tunnel devices positioned in a plurality of rows and a plurality of columns of an array;
a plurality of row conductors that are aligned with a row direction of the array; and
a plurality of column conductors that are aligned with a column direction of the array,
each of the plurality of the magnetic tunnel junction devices is positioned between an intersection of one of the row conductors with one of the column conductors,
wherein the plurality of row conductors comprises a selected one of the dual-damascene conductor or the bottom conductor, and
wherein the plurality of column conductors comprises a selected one of the dual-damascene conductor or the bottom conductor.

33. The magnetic tunnel junction device as set forth in claim 32, wherein the array is a MRAM array.

34. The magnetic tunnel junction device as set forth in claim 32, wherein the tunnel barrier layer is made from a dielectric material.
